(19) United States
(12) Patent Application Publication
(10) Pub. No.: US 2026/0104365 A1
(43) Pub. Date: Apr. 16, 2026

(54) EDGE DETECTION IN AN IMAGE OF A SEMICONDUCTOR SPECIMEN

(71) Applicant: Applied Materials Israel Ltd., Rehovot (IL)

(72) Inventors: Omri BRAND, Rehovot (IL); Shahar ARAD, Holon (IL); Ilan BEN-HARUSH, Tel-Aviv (IL); Tal FRANK, Tel-Aviv (IL); Rafael BISTRITZER, Petach Tikva (IL)

(21) Appl. No.: 18/915,286

(22) Filed: Oct. 14, 2024

(51) Int. Cl. G01N 21/95; G01N 21/88

(52) U.S. Cl. CPC G01N 21/9503; G01N 21/8851; G01N 2021/8861; G01N 2021/8877; G01N 2021/8887

(57) ABSTRACT

There are provided systems and methods comprising obtaining an image informative of at least part of at least one structural element of a semiconductor specimen, using the image to generate one or more filters, performing a comparison between each given area of a plurality of areas of the image, and the one or more filters, and determining, based on the comparison, a set of points of the image, informative of an estimated position of at least one edge of the at least one structural element in the image, the set of points comprising, for each given row of a plurality of rows of the image, or for each given column of a plurality of columns of the image, at least one given point of the given row or of the given column of the image.

### TECHNICAL FIELD

The presently disclosed subject matter relates, in general, to the field of examination of a specimen, and more specifically, to automating the examination of a specimen.

### BACKGROUND

Current demands for high density and performance associated with ultra large-scale integration of fabricated devices require submicron features, increased transistor and circuit speeds, and improved reliability. Such demands require formation of device features with high precision and uniformity, which, in turn, necessitates careful monitoring of the fabrication process, including automated examination of the devices while they are still in the form of semiconductor wafers.

Examination processes are used at various steps during semiconductor fabrication to measure dimensions of the specimens (metrology), and/or to detect and classify defects on specimens (e.g., Automatic Defect Classification (ADC), Automatic Defect Review (ADR), etc.).

### GENERAL DESCRIPTION

In accordance with certain aspects of the presently disclosed subject matter, there is provided a system comprising one or more processing circuitries configured to: obtain an image informative of at least part of at least one structural element of a semiconductor specimen, use the image to generate one or more filters, perform a comparison between each given area of a plurality of areas of the image, and the one or more filters, and determine, based on the comparison, a set of points of the image, informative of an estimated position of at least one edge of the at least one structural element in the image, the set of points comprising, for each given row of a plurality of rows of the image, or for each given column of a plurality of columns of the image, at least one given point of the given row or of the given column of the image.

In addition to the above features, the system according to this aspect of the presently disclosed subject matter can comprise one or more of features (i) to (xxii) listed below, in any desired combination or permutation which is technically possible:
(i). for said each given row or said each given column, the comparison indicates, for the given point, a best match within said each given row or said each given column;
(ii). the comparison enables outputting a set of scores, wherein, for said each given row or for said each column, a given score of the given point is the highest among scores of points of the said each given row or of the said each given column;
(iii). using the image to generate the one or more filters comprises averaging pixel intensity along rows or columns of the image;
(iv). using the image to generate the one or more filters comprises using a machine learning model and the image to generate the one or more filters;
(v). for each given row of a plurality of rows of the image, or for each column of a plurality of columns of the image, the system is configured to determine a given distance between the given point belonging to the given row or to the given column, and a reference line which is based on said set of points, thereby obtaining a set of distances, use the image and the set of distances to generate a corrected image, and use the corrected image to determine another estimate of the position of the at least one edge in the image;
(vi). for each given row of a plurality of rows of the image, or for each given column of a plurality of columns of the image, the system is configured to determine a given distance between the given point belonging to the given row or to the given column, and a reference line which is based on said set of points, use the given distance to perform a displacement of said each given row or of said each given column, wherein the given distance differs between at least two rows or two columns of the image, thereby obtaining a corrected image, and use the corrected image to determine another estimate of the position of the at least one edge in the image;
(vii). the system is configured to determine at least one point of the set of points located at a distance from an average position of the set of points above a first threshold;
(viii). the system is configured to determine at least one point of the set of points located at a distance from an average position of the set of points above a first threshold;
(ix). the system is configured to determine at least one point of the set of points located at a distance from an average position of the set of points which differs from a distance of other points of the set of points to said average position, by a second threshold;
(x). each point of the set of points is associated with a score obtained based on said comparison, wherein the system is configured to identify a point of the set of points, which is associated with a score which differs from scores of other points of the set, or from an aggregated score of the set, by a threshold, and raise an alert informative of said point, or of a row or a column comprising said point;
(xi). the comparison enables generating a set of scores, wherein the system is configured to identify a given row, or a given column of the image, associated with an aggregated score informative of various scores within said given row or said given column, which differs from aggregated scores of other rows, or other columns, of the image, by a difference above a threshold, and raise an alert informative of said given row or said given column;
(xii). the system is configured to estimate a position of different edges based on different filters, perform a comparison between the different filters, and use this comparison to determine whether a defect is present in one or more of said different edges;
(xiii). the system is configured to obtain an initial image comprising a plurality of edges of one or more structural elements, split the initial image into a plurality of images, each including a different given edge of the plurality of edges, for each given image of the plurality of images, use the given image to generate one or more given filters, perform a comparison between each given area of a plurality of areas of the given image and the one or more filters, and determine, based on the comparison, a given set of points of the given image, informative of an estimated position of the given edge in the given image, the given set of points comprising, for each given row of a plurality of rows of the given image, or for each given column of a plurality of columns of the given image, at least one given point of the given row or of the given column of the given image;
(xiv). the system is configured to use the image to generate a set of filters, perform a comparison between each given area of a plurality of areas of the image, and the set of filters, and use said comparison to determine the set of points of the image, informative of an estimated position of the edge;
(xv). the system is configured to generate a cell informative of repetitive features of the image, and to use the cell to generate the set of filters;
(xvi). the system is configured to perform a comparison between each respective row, or each respective column, of the given area, with a respective filter of the set of filters;
(xvii). the system is configured to: (1) for a current area of the plurality of areas, perform a comparison between each respective row, or each respective column, of the current area, with a respective filter of the set of filters, (2) when all rows, or all columns of the current area, have been compared, repeat (1) for a next area of the plurality of areas, different from the current area;
(xviii). the system is configured to perform a comparison between each given row, or each given column, of the given area, with a filter of the set of filters, associated with a row, or a column, of the cell, which has a position relative to the cell corresponding to a position of said given row or said given column relative to the given area;
(xix). the system is configured to perform a comparison between each given row, or each given column, of the given area, with a filter of the set of filters, associated with a row, or a column, of the cell, with a position relative to the cell corresponding to a position of said given row or said given column relative to the given area, and at least another filter of the set of filters, associated with a row, or a column, of the cell, with a position relative to the cell which differs from the position of said given row or said given column relative to the given area;
(xx). the one or more filters comprise a set of filters, wherein the system is configured to use the image to generate the set of filters with different dimensions among filters of the set;
(xxi). the one or more filters comprise a set of filters, wherein the system is configured to use the image to generate the set of filters with different dimensions among filters of the set, wherein the structural element is located in a first layer of the specimen, wherein, for at least one filter of the set of filters, a dimension of said at least one filter depends on a position of one or more other structural element of the specimen, located in a second layer of the specimen, different from the first layer;
(xxii). the system is configured to obtain an initial image of the structural element acquired by an examination tool and convert the initial image into the image informative of the at least part of the structural element, wherein the image includes a plurality of lines informative of pixel intensity along different axes of the initial image, associated with different orientations.

In accordance with certain aspects of the presently disclosed subject matter, there is provided a computer-implemented method comprising obtaining an image of a semiconductor specimen, wherein the image is informative of at least part of at least one structural element of the semiconductor specimen, using the image to generate one or more filters, performing a comparison between each given area of a plurality of areas of the image, and the one or more filters, and determining a set of points of the image, informative of an estimated position of at least one edge of the at least one structural element in the image, the set of points comprising, for each given row of a plurality of rows of the image, or for each given column of a plurality of columns of the image, at least one given point of the given row or of the given column of the image for which the comparison meets a criterion.

The method can comprise one or more of features (i) to (xxii) listed above with respect to the system, mutatis mutandis, in any desired combination or permutation which is technically possible.

In accordance with other aspects of the presently disclosed subject matter, there is provided a non-transitory computer readable medium comprising instructions that, when executed by one or more processing circuitries, cause the one or more processing circuitries to perform operations described with reference to the method above.

The proposed solution provides various technical advantages. At least some of them are listed hereinafter.

According to some examples, the proposed solution enables efficient and accurate detection of edges of structural elements in an image of a semiconductor specimen. The structural elements can include e.g., electrical lines, contacts, gates, holes, transistors. This list is not limitative.

According to some examples, the proposed solution enables efficient and accurate detection of edges in an image of a semiconductor specimen with a low or very low signal-to-noise ratio (SNR).

According to some examples, the proposed solution enables efficient and accurate detection of edges in an image including UV (ultraviolet) layers (e.g., layers manufactured using Extreme ultraviolet radiation).

According to some examples, the proposed solution enables reduction of the energy of the electron beam used to acquire images of a semiconductor specimen. As a consequence, the physical impact of the electron beam on the semiconductor specimen is reduced.

According to some examples, the proposed solution is invariant to process variation.

According to some examples, the proposed solution enables edge detection of structural elements, without requiring prior knowledge on the edge(s) and/or on the structural elements.

According to some examples, the proposed solution enables detection of various defects such as process variation, edge roughness, short-circuit, absence of missing feature (such as, but not limited to, electrical lines), bridges, necking, etc.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain examples of the presently disclosed subject matter.

FIG. 2A illustrates a non-limitative example of an image of a specimen.

FIG. 2B illustrates a non-limitative example of extraction of a structural element from the image of FIG. 2A.

FIG. 2C illustrates a non-limitative example of extraction of an edge from the image of FIG. 2A.

FIG. 3A illustrates a generalized flow-chart of a method of estimating the position of edges in an image of a specimen, in accordance with certain examples of the presently disclosed subject matter.

FIG. 3B illustrates a generalized flow-chart of a method of estimating the position of edges in an image of a specimen, using an iterative process, in accordance with certain examples of the presently disclosed subject matter.

FIG. 3C corresponds to a particular implementation of the method of FIG. 3B.

FIG. 4A depicts a non-limitative example of an image of part of a specimen, which includes an edge of an electrical line to be detected.

FIG. 4B depicts a non-limitative example of a filter generated based on the image of FIG. 4A.

FIG. 5 depicts a non-limitative example of isolating two edges of an electrical conductor, from an image of the electrical conductor.

FIG. 6 illustrates a non-limitative example of different rows of the image of FIG. 4, which are each compared to a filter.

FIG. 7 illustrates a non-limitative example of an estimate of the edge of an electrical line in an image of a specimen.

FIG. 8 illustrates a non-limitative example of the identification of certain points.

FIG. 9 illustrates a non-limitative example of the determination of a distance, for each row, between a point associated with the highest score in this row, and an average position of a set of points.

FIG. 10 illustrates a non-limitative example of generation of a corrected image.

FIG. 11 illustrates a non-limitative example of a corrected image.

FIG. 12A illustrates a generalized flow-chart of a method of estimating the position of an edge of a structural element in an image of a specimen, using an iterative process, in accordance with certain examples of the presently disclosed subject matter.

FIG. 12B illustrates a generalized flow-chart of a method of estimating the position of an edge of a structural element an image of a specimen, using an iterative process, in accordance with certain examples of the presently disclosed subject matter.

FIG. 13 illustrates a generalized flow-chart of a method of estimating the position of an edge of a structural element an image of a specimen, based on a plurality of filters, in accordance with certain examples of the presently disclosed subject matter.

FIG. 14A illustrates a generalized flow-chart of a method of estimating the position of an edge of a structural element in an image of a specimen, using an iterative process and a plurality of filters, in accordance with certain examples of the presently disclosed subject matter.

FIG. 14B illustrates a generalized flow-chart of a method of generating a plurality of filters based on a golden cell.

FIG. 15 illustrates a non-limitative example of an image of a specimen including a plurality of layers.

FIG. 16 illustrates a non-limitative example of a golden cell generated based on the image of FIG. 15.

FIG. 17 illustrates a non-limitative example of a plurality of filters generated based on the golden cell of FIG. 16.

FIG. 18 illustrates a non-limitative example of a comparison between an image of a specimen and a plurality of filters.

FIG. 19 illustrates a non-limitative example of an image of a specimen, in which at least one edge is associated with process variation.

FIG. 20 illustrates a generalized flow-chart of a method of comparing an image of a specimen with a plurality of filters, in accordance with certain examples of the presently disclosed subject matter.

FIG. 21 illustrates an example of the method of FIG. 20.

FIG. 22 illustrates a generalized flow-chart of a method of generating a plurality of filters with different dimensions, in accordance with certain examples of the presently disclosed subject matter.

FIG. 23 illustrates an example of the method of FIG. 22.

FIG. 24 illustrates a generalized flow-chart of a method of generating one or more filters, in accordance with certain examples of the presently disclosed subject matter.

FIG. 25 illustrates a generalized flow-chart of a method of identifying rows or columns associated with a defect, in accordance with certain examples of the presently disclosed subject matter.

FIG. 26 illustrates a generalized flow-chart of another method of identifying rows or columns associated with a defect, in accordance with certain examples of the presently disclosed subject matter.

FIG. 27A illustrates a generalized flow-chart of a method of identifying defects in an edge, by comparing an aggregated score associated with this edge with aggregated scores of other edges.

FIG. 27B illustrates a non-limitative example of the method of FIG. 27A.

FIG. 28 illustrates a generalized flow-chart of a method of identifying a defect in an edge, by comparing a filter used to determine the position of this edge with other filters used to determine the position of other edges.

FIG. 29 illustrates a generalized flow-chart of a method of estimating the position of the contour (edges) of an element, usable for any shape of the contour, in accordance with certain examples of the presently disclosed subject matter.

FIG. 30 illustrates a non-limitative example of an image of an element with an elliptical contour.

FIG. 31 illustrates a conversion of the image of FIG. 30 into a matrixial representation.

FIG. 32 illustrates a generalized flow-chart of a method of converting an image of an element into a matrixial representation, in accordance with certain examples of the presently disclosed subject matter.

### DETAILED DESCRIPTION OF EMBODIMENTS

A semiconductor specimen includes various structural elements, such as (but not limited to) electrical connectors/lines, contacts, gates, holes, transistors. It is intended to detect the edges of these structural elements, in an image of the specimen, such as in a Scanning Electron Microscope image. At least one filter is generated based on an average of the pixel intensity of an image of the specimen. Note that this filter can be generated using different methods. The filter is compared to one or more areas of the image. This comparison enables assigning a score to each point of a plurality of points of the image. For example, a high score indicates a match, and a low score indicates a mismatch. For each row of the image, at least one point is identified, which corresponds to the point of the row with the highest score. Note that it is possible to identify, for each row, a single point (corresponding to the highest score), or a plurality of points (corresponding to the highest scores).

A set of points is obtained. This set of points constitute or is usable to estimate the position of the edge of a structural element of the specimen. The points of the set form a line, which constitutes a first estimate of the position of the edge.

In some examples, the set of points can be used to generate a corrected image which is used to fine-tune this first estimate of the position of the edge of the specimen. For each row, a distance between the point of the set and the reference line is computed. Each row of the image is then translated by its respective value of the computed distance, to obtain a corrected image. The method is then repeated with the corrected image. One or more filters are computed based on the corrected image, which are then compared to the original image, in order to identify a set of points corresponding to a new estimate of the position of the edge. The method can be used to estimate the position of various edges in the image.

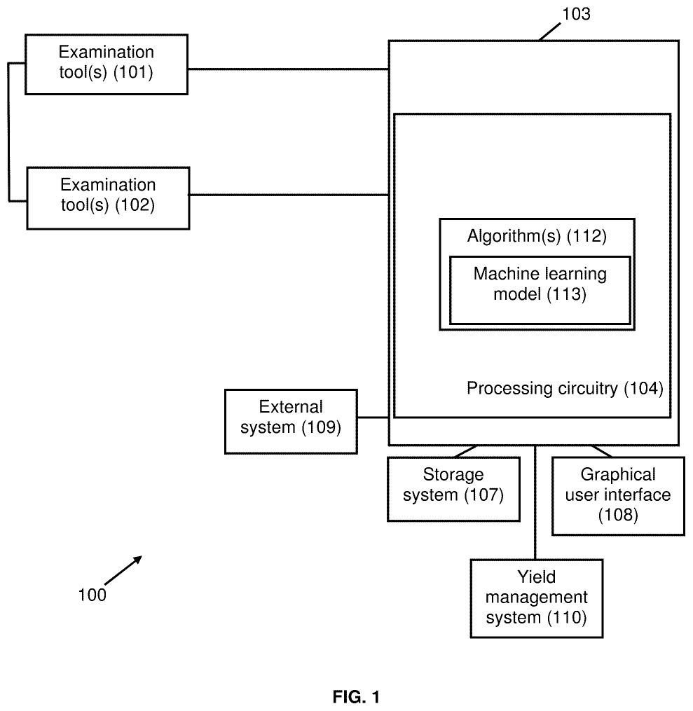

Attention is drawn to FIG. 1 illustrating a functional block diagram of an examination system 100 in accordance with certain examples of the presently disclosed subject matter. The examination system 100 illustrated in FIG. 1 can be used for examination of a specimen (e.g., of a wafer and/or parts thereof) as part of the specimen fabrication process. The illustrated examination system 100 comprises computer-based system 103 capable of automatically determining metrology information and/or defect-related information using images obtained during specimen fabrication. System 103 can be operatively connected to one or more examination tools 101, 102. The examination tools are configured to capture images and/or to review the captured image(s) and/or to enable or provide measurements related to the captured image(s). In some examples, the examination tool(s) can correspond to one or more inspection tool(s) 101 and the examination tool(s) can correspond to one or more review tool(s) 102.

The examination tool(s) 101, 102 can include at least one of: an optical examination tool (such as, but not limited to, the Enlight™ tool of the Applicant), an electron beam examination tool (such as a SEM), an Atomic Force Microscopy (AFM), etc. In some cases, the same examination tool can provide low-resolution image data and high-resolution image data. In some cases, at least one examination tool can have metrology capabilities.

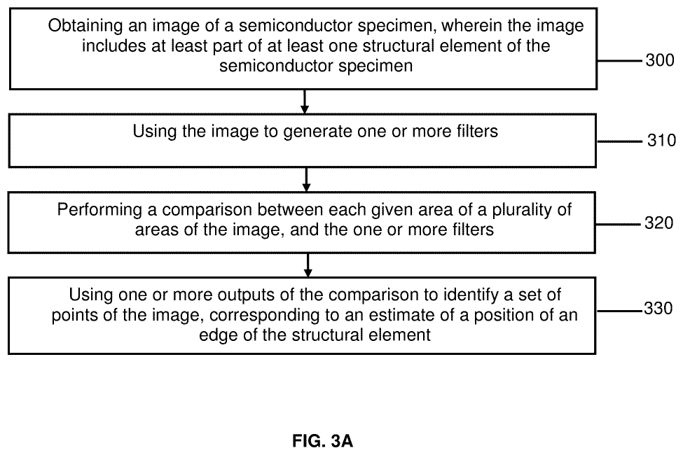

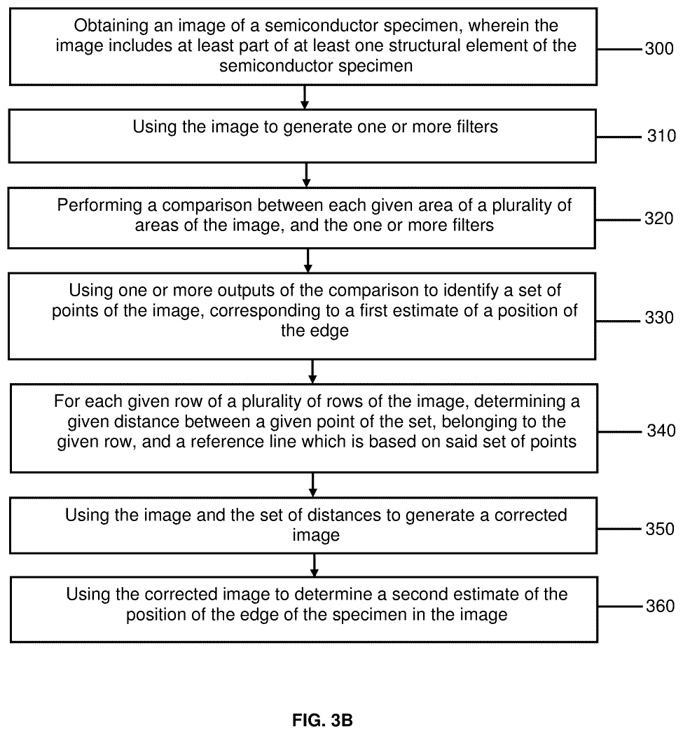

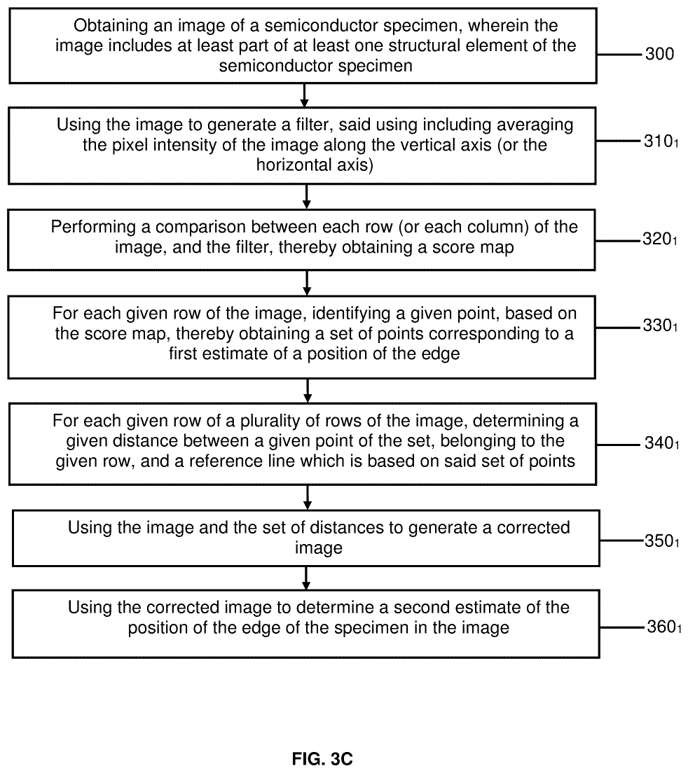

System 103 includes a processing circuitry 104, which includes one or more processors and one or more memories. The processing circuitry 104 is configured to provide all processing necessary for operating the system 103, as further detailed hereinafter (see methods described in FIGS. 3A, 3B, 3C, 12A, 12B, 13, 14A, 14B, 20, 22, 24, 25, 26, 27A, 28, 29 and 32 which can be performed at least partially by system 103 and/or system 100).

The processing circuitry 104 is configured to execute functional modules in accordance with computer-readable instructions implemented on a non-transitory computer-readable memory of the processing circuitry 104 (or operatively coupled to the processing circuitry 104). The functional modules include one or more algorithms 112.

In some examples, the algorithm(s) 112 can include a machine learning algorithm. Examples of machine learning algorithms include e.g., decision tree, Support Vector Machine (SVM), Artificial Neural Network (ANN), regression model, Bayesian network, etc., or ensembles/combinations thereof. In some embodiments, the machine learning algorithm can be implemented as a deep neural network (DNN). DNN can comprise multiple layers organized in accordance with respective DNN architecture. By way of non-limiting example, the layers of DNN can be organized in accordance with Convolutional Neural Network (CNN) architecture, Recurrent Neural Network architecture, Recursive Neural Networks architecture, Generative Adversarial Network (GAN) architecture, or otherwise. Optionally, at least some of the layers can be organized into a plurality of DNN sub-networks. Each layer of DNN can include multiple basic computational elements (CE) typically referred to in the art as dimensions, neurons, or nodes.

The weighting and/or threshold values associated with the CEs of a deep neural network and the connections thereof can be initially selected prior to training, and can be further iteratively adjusted or modified during training to achieve an optimal set of weighting and/or threshold values in a trained DNN. After each iteration, a difference can be determined between the actual output produced by the DNN module and the target output associated with the respective training set of data. The difference can be referred to as an error value. Training can be determined to be complete when a loss/cost function indicative of the error value is less than a predetermined value, or when a limited change in performance between iterations is achieved. A set of input data used to adjust the weights/thresholds of a deep neural network is referred to as a training set.

System 103 is configured to receive input data. Input data can include data (and/or derivatives thereof and/or metadata associated therewith) produced by the examination tools 101, 102, and/or data generated based on the output of the examination tools. It is noted that input data can include at least one of: images (e.g., captured images, images derived from the captured images, simulated images, synthetic images, etc.), associated numeric data (e.g., metadata, hand-crafted attributes, etc.). It is further noted that image data can include data related to a layer of interest and/or to one or more other layers of the specimen. It is noted that image data can be received and processed together with metadata (e.g., pixel size, text description of defect type, parameters of image capturing process, etc.) associated therewith.

System 103 can send instructions to any of the examination tool(s) 101, 102, store the results (such as data informative of the location of the defects) in a storage system 107, and render the results via a computer-based graphical user interface GUI 108, and/or to an external system 109 and/or to a yield management system (YMS) 110. A yield management system (YMS) is a data management, analysis, and tool system that collects data from the fab, especially during manufacturing ramp ups, in order to improve yield.

Those versed in the art will readily appreciate that the teachings of the presently disclosed subject matter are not bound by the system illustrated in FIG. 1: equivalent and/or modified functionality can be consolidated or divided in another manner and can be implemented in any appropriate combination of software with firmware and/or hardware.

It is noted that the examination system illustrated in FIG. 1 can be implemented in a distributed computing environment, in which the aforementioned functional modules shown in FIG. 1 can be distributed over several local and/or remote devices, and can be linked through a communication network. It is further noted that in some embodiments at least some of the examination tools 101 and/or 102, storage system 107, external system 109, GUI 108, YMS 110 can be external to the examination system 100 and operate in data communication with system 103. System 103 can be implemented as stand-alone computer(s) to be used in conjunction with the examination tools. Alternatively, the respective functions of the system can, at least partly, be integrated with one or more examination tools.

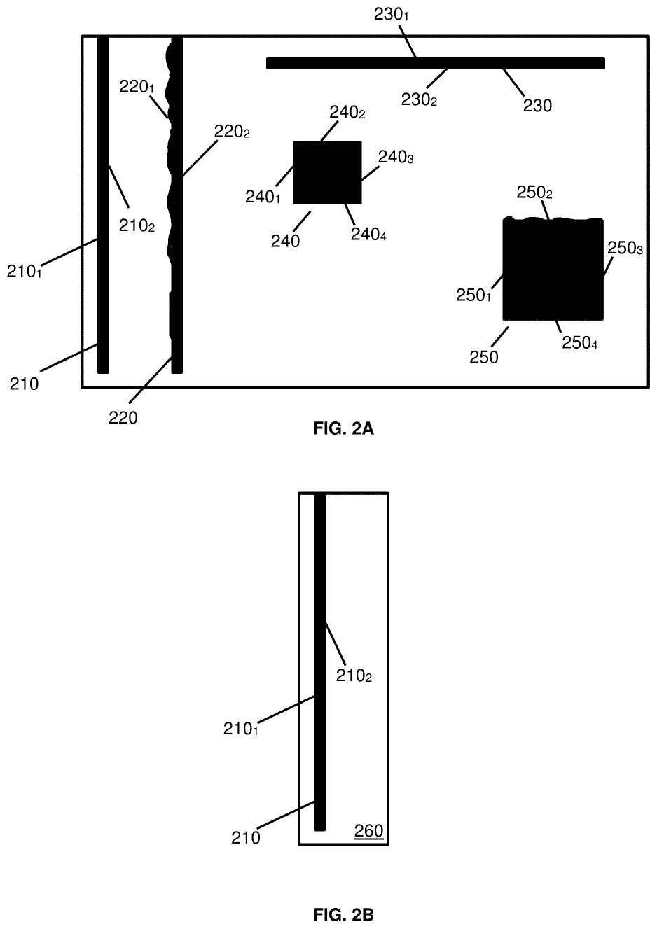

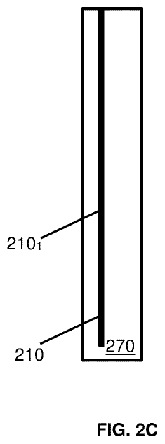

Attention is now drawn to FIG. 2, which depicts a non-limitative example of an image 200 of a specimen.

The specimen includes a plurality of structural elements. In this non-limitative example, the structural elements include electrical connectors 210, 220 and 230 (also called electrical lines). In this example, the electrical connectors 210 and 220 extend along the vertical axis (column axis) of the image, and the electrical connector 230 extends along the horizontal axis (row axis). Each electrical connector includes two edges: see left and right edges 210₁, 210₂ for connector 210, left and right edges 220₁, 220₂ for connector 220, top and bottom edges 230₁, 230₂ for connector 230.

The specimen includes additional structural elements, schematically depicted as squares 240, 250, each including respective edges 240₁, 240₂, 240₃, 240₄, 250₁, 250₂, 250₃ and 250₄.

Various methods are provided hereinafter, enabling determining the position of one or more edges of a specimen (see non-limitative example of edges in FIG. 2), based on an image of the specimen acquired by an examination tool. In the description, it is referred to the processing of an image. This image includes in a broad sense a group of pixels, each associated with at least one pixel intensity. This image can correspond to an image acquired by an examination tool, and/or to an image derived from the image acquired by the examination tool. In particular, the image processed in the various methods described hereinafter can correspond to an image acquired by an examination tool after one or more pre-processing operations. In some examples (see FIGS. 29 to 32), the image corresponds to matrixial representation obtained from the initial image acquired by the examination tool, in which the pixels of the initial image are rearranged such that the edges of the element are included within a vertical band (strip) of the image.

One or more of the edges can be associated with process variation (see e.g., edge 220₁ and 250₂). As explained hereinafter, according to some examples, data informative of process variation (also called edge roughness) can be obtained.

Attention is now drawn to FIGS. 3A, 3B and 3C, which depict methods enabling determination of the position of one or more edges in an image of a specimen. The method of FIG. 3B corresponds to the method of FIG. 3A, in which an iterative process is performed to determine the position of the edge(s). The method of FIG. 3C corresponds to a particular implementation of the method of FIG. 3B.

The methods of FIGS. 3A to 3C include obtaining (operation 300) at least one image of a semiconductor specimen. The image has been acquired by an examination tool (see 101, 102 in FIG. 1) such as an electron beam examination tool (SEM), or has been generated based on an image acquired by the examination tool.

The image includes at least part of at least one structural element of the semiconductor specimen. In some examples, an image of the specimen is acquired by the examination tool, and processed to include a single structural element, or a single edge of a single structural element. This can be performed by using one or more existing edge detection algorithm(s). In other words, each edge to be detected can be isolated in a different image and processed using the various methods described hereinafter.

Note that the same process can be performed for each edge of the specimen that needs to be detected, such that an image including a single structural element (or a single edge) is generated for each structural element (or for each edge), which is then processed according to the various methods described hereinafter, in order to determine the position of the edge.

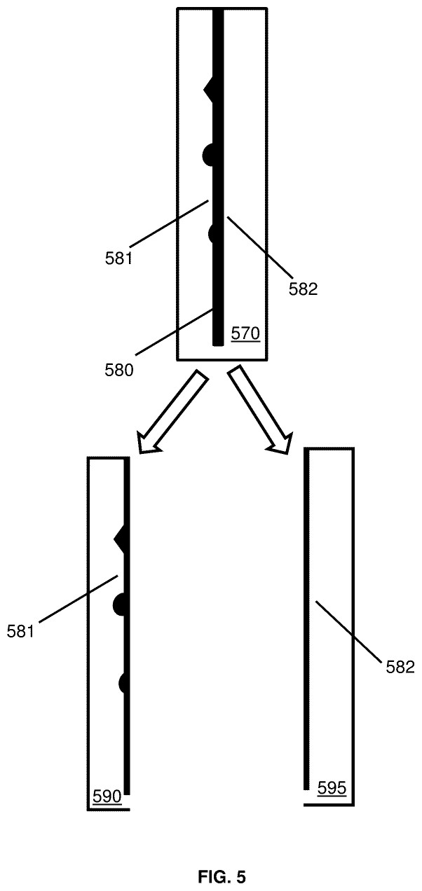

A non-limitative example is provided in FIG. 2B, in which the image 260 has been generated based on the image 200 and includes only the structural element 210. Another non-limitative example is provided in FIG. 2C, in which the image 270 has been generated based on the image 200 and includes only the left edge 210₁ of the structural element 210. Another non-limitative example is provided in FIG. 5, in which the image 570 of the electrical conductor 580 (also called electrical line) is split into a first image 590 including only the left edge 581 of the electrical conductor 580 and into a second image 595 including only the right edge 582 of the electrical conductor 580.

The methods of FIGS. 3A to 3C further include using (operation 310) the image to generate one or more filters. An image includes a plurality of pixels, each associated with a pixel intensity (also called grey level intensity). In some examples, the filter(s) can be generated by averaging the pixel intensity of a plurality of pixels. In some other examples, a machine learning algorithm 112 can be used to generate the filter(s) based on the image.

In the method of FIG. 3C, this includes averaging (operation 310₁) the pixel intensity of the image along an axis, such as the vertical axis (or the horizontal axis). When an edge extending mainly along the vertical axis has to be detected, such averaging is performed along the vertical axis. When an edge extending mainly along the horizontal axis has to be detected, such averaging is performed along the horizontal axis.

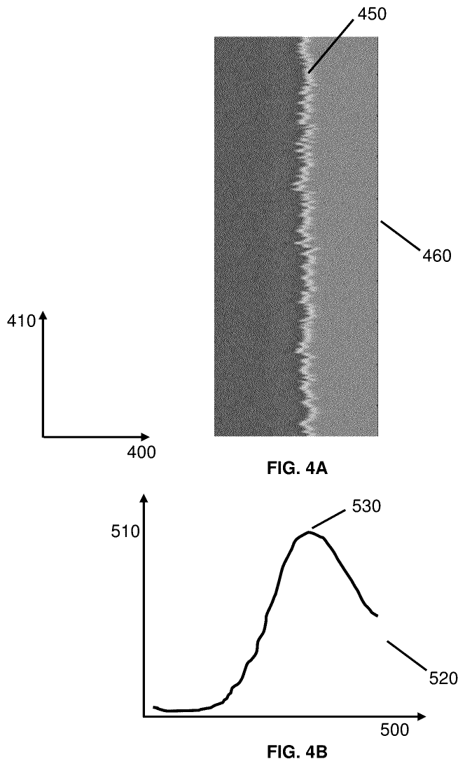

A non-limitative example of operation 310₁ is provided in FIGS. 4A and 4B. FIG. 4A depicts a non-limitative example of an image 460 of part of a specimen, which includes an edge 450 to be detected. The horizontal axis is noted 400 and the vertical axis is noted 410.

FIG. 4B depicts the projection of the pixel intensity of the image 460 along the vertical axis 410. This projection is performed by averaging the pixel intensity of the image 460 along the vertical axis 410. The signal 520 is obtained. Axis 500 of the graph corresponds to the horizontal axis 400 of the image and axis 510 of the graph corresponds to the pixel intensity. As visible in FIG. 4B, the peak 530 of the signal 520 coincides, along the horizontal axis (400 or 500), with the position of the edge 450 along the horizontal axis.

Note that an electrical conductor (also called electrical line) can include two edges. For example (see FIG. 5), assume that the electrical conductor 510 extends along the vertical axis of the image. In this case, the electrical conductor 510 includes a left edge 520 and a right edge 530. As illustrated in FIG. 5, it is possible to generate, based on an image 500 of the electrical conductor 510, a first image 550 including the left edge 520 (and not the right edge 530), and a second image 560 including the right edge 530 (and not the left edge 520). In this case, a first filter is generated for the first image 550 including the left edge 520 and a second filter is generated for the second image 560 including the right edge 530.

The methods of FIGS. 3A and 3B further include performing (operation 320) a comparison between each given area of a plurality of areas of the image, and the one or more filters. This comparison indicates to which extent the pixel intensity distribution of each given area matches the pixel intensity distribution of the one or more filters. Various methods can be used to perform this comparison, such as (but not limited to), cross-correlation, normalized cross correlation, least square method, etc.

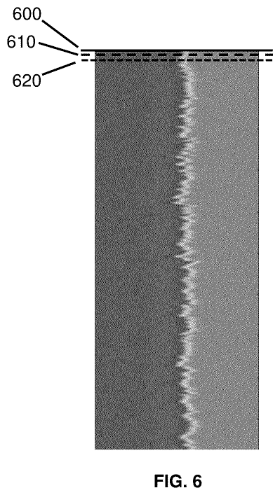

In the method of FIG. 3C, each row of the image is compared to the filter (operation 3201). This comparison includes comparing the pixel intensity profile along the row with the pixel intensity profile of the filter (see e.g., the pixel intensity profile 520 in FIG. 5). FIG. 6 illustrates a non-limitative example of different rows 600, 610, and 620 of the image, which are each compared to the filter 520.

Note that in some other examples, the filter has been generated by projecting the pixel intensity along the row axis (horizontal axis). In this case, each column of the image is compared to the filter.

The methods of FIGS. 3A and 3B further include using (operation 330) one or more outputs of the comparison to identify a set of points of the image.

For each given row of each given column, at least one given point is identified, for which the comparison indicates a match. The match can be assessed according to a criterion. In some examples, the given point can be identified as the point for which there is the best match within the given row (or the given column).

The comparison enables assigning a score to each of a plurality of pixels of the image. Note that a score can be assigned to one or more sub-pixels of the image (points located between the pixels) by interpolating the scores of the adjacent pixels, and/or by using a parabola. A score map is therefore obtained. Each score indicates the level of matching between the pixel intensity at this location, and the corresponding pixel intensity of the filter(s). For example, a high score indicates a high level of matching, and a low score indicates a low level of matching.

As recited in operation 330₁ of FIG. 3C, for each given row of the image, at least one given point can be identified based on the score map. In particular, for each given row, the given point can be selected as the pixel (or sub-pixel) of the given row with the highest score. As mentioned above, it can occur that the comparison is performed between the columns of the image and the filter(s). In this case, the points are identified along the column axis.

The points of the set (see e.g., reference 700 in FIG. 7) of points constitute a first estimate of the position of the edge of the structural element present in the image.

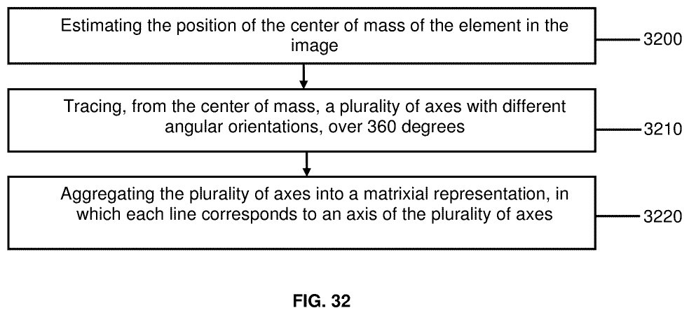

Note that this method can be used to estimate the position of curved edges, or of edges with various different shapes. This will be also discussed with reference to FIGS. 29 and 32.

In some examples, it is possible to identify certain points of the set which have a certain likelihood to be inaccurate or irrelevant (these points are also called “outliers”).

The points of the set, which are located at a distance from the average position of the set of points above a first threshold, can be identified. Similarly, the points which are located at a distance from the average position of the set of points, which differs significantly (e.g. by a second threshold, which can be the same as the first threshold, or different from the first threshold) from the distance of the other points from the average position of the set of points, can be identified.

These outliers may be excluded from the set of points and/or ignored when further processing the set of points, since they may correspond to invalid points.

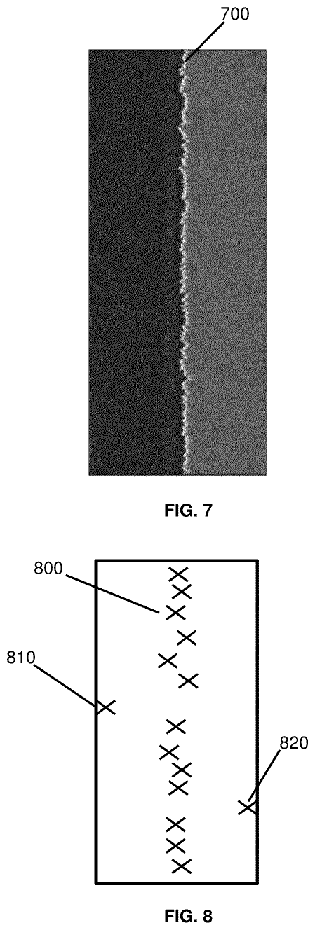

A non-limitative example is illustrated in FIG. 8, in which the points 810 and 820 are excluded from the set of points, since their distance to the average position of the set of points 800 is significantly higher than the other points. These points are considered as outliers.

In some examples, if, for a given row (or a given column), the given point associated with the highest score (for this given row or column) is such that its score is significantly below the scores of the other points (belonging to other rows or columns) of the set, this given point can be ignored. For example, assume that the score in the score map is on a scale between −1 and +1. Assume that most points (corresponding to the highest score per row or per column) have a score between 0.8 and +1. Assume that, for a given row, the given point with the highest score has a score equal to +0.2. This given point can be ignored and will not be part of the set of points.

As explained hereinafter, in some examples, a corrected image is generated based on the set of points and the image. The points of the set that have been identified (either because of their low score relative to the other points, or because of their different distance to the average position of the set of points) may be ignored when generating the corrected image. The corrected image can be generated based on a limited subset of points of the set of points, wherein the subset does not include one or more of the points to be ignored. As explained hereinafter, in order to generate the corrected image, each row may be translated by a distance depending on the distance between the point of the set belonging to this row, and the average position of the set of points. Rows which include a point to be ignored are not translated. The same processed can be performed along the columns (instead of performing the process along the rows).

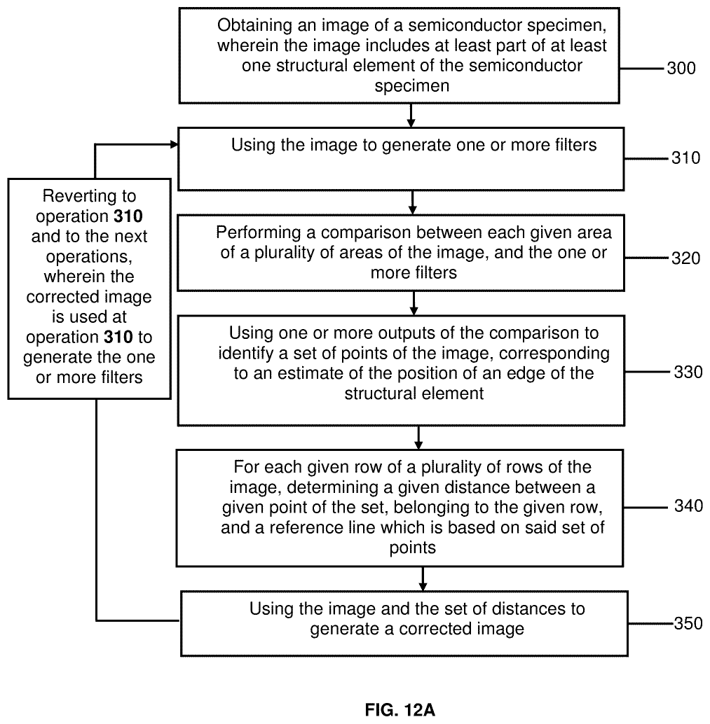

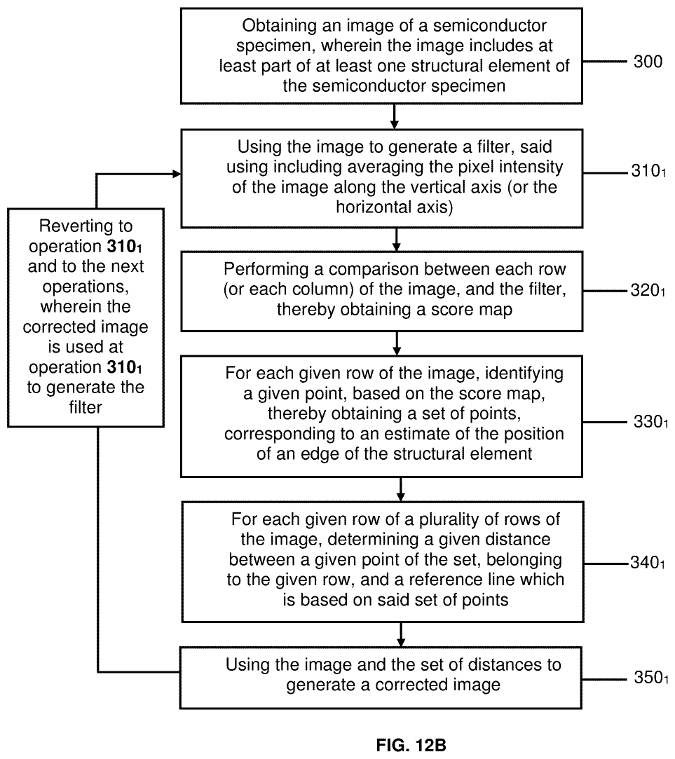

In some examples, several iterations can be performed. At each iteration, it is attempted to fine-tune the estimate of the position of the edge with respect to the previous iteration. An iterative process is described in FIGS. 3B and 3C. Further examples of the iterative process are further described hereinafter in FIGS. 12A and 12B.

The methods of FIGS. 3B and 3C further include (operation 340 in FIGS. 3B and 3401 in FIG. 3C), for each given row of a plurality of rows of the image (or for each column of a plurality of columns of the image), determining a given distance between a given point of the set, belonging to the given row (or to the given column), and a reference line which is based on said set of points. This enables obtaining a set of distances (one per row, or one per column).

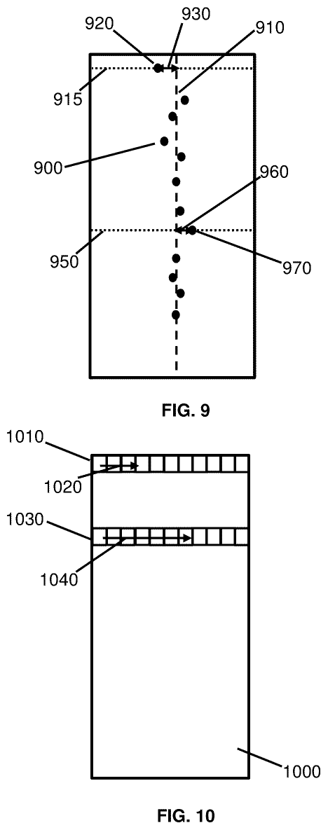

A non-limitative example is depicted in FIG. 9, which depicts a set of points 900, and a reference line 910 corresponding to the average position of the points 900 along the horizontal axis of the image. For each row, the distance between the point of the row and the reference line 910 is computed. For example, for row 915, the distance 930 between the point 920 and the reference line 910 is computed. For row 950, the distance 960 between the point 970 and the reference line 910 is computed.

The methods of FIGS. 3B and 3C further include using (operation 350 in FIG. 3B and operation 350₁ in FIG. 3C) the image and the set of distances to generate a corrected image. In particular, each row can be translated by the distance of the set of distances computed for this row. Note that this can be performed similarly with the columns.

A non-limitative example is provided in FIG. 10. Assume that the image 1000 includes a row 1010 of pixels. Assume that it has been determined at operation 340 or 340₁ that the distance between the point of this row 1010 and the average position of the set of points is equal to the length of the arrow 1020. The entire row 1010 of pixels is then translated by a translation vector corresponding to the arrow 1020.

Assume that the image 1000 includes another row 1030 of pixels. Assume that it has been determined at operation 340 or 340₁ that the distance between the point of this row 1030 and the average position of the set of points is equal to the length of the arrow 1040. The entire row 1030 of pixels is then translated by a translation vector corresponding to the arrow 1040.

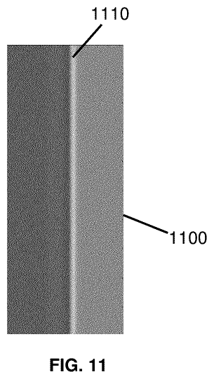

In the corrected image, the set of points is substantially aligned along a line. A non-limitative example is provided in FIG. 11, which depicts the corrected image 1100 and the set 1110 of points.

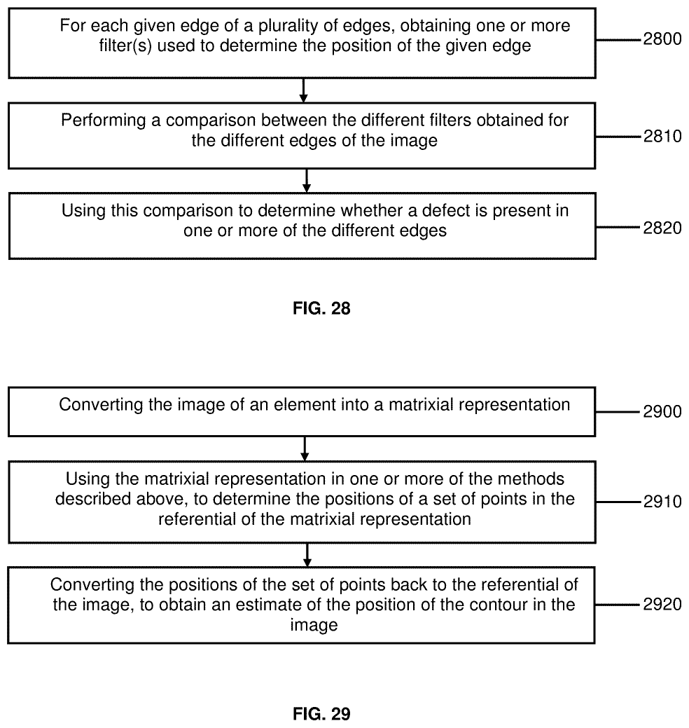

The methods of FIGS. 3B and 3C further include (operation 360 in FIG. 3B and operation 360₁ in FIG. 3C) using the corrected image to estimate a position of an edge of a structural element of the specimen in the image. The set of points (obtained at operation 330 or 330₁) corresponds to a first estimate of the position of the edge. The corrected image is used to fine-tune this first estimate, and to obtain a second estimate of the position of the edge (operation 360 and 360₁). Note that the second estimate can be further fine-tuned (N iteration(s) of the method can be performed, with N≥1). This is depicted in FIGS. 12A and 12B. Note that the methods of FIGS. 3B and 3C can be used to estimate the position of curved edges, or of edges with various different shapes. This will be also discussed with reference to FIGS. 28 and 29.

FIG. 12A illustrates operations 300 to 350 already described above with reference to FIGS. 3A and 3B. At operation 350, the corrected image is generated. Then, it is reverted to operation 310, in which one or more filters (new filter(s), which differ from the filters generated at the previous iteration), are generated. At this iteration of operation 310, the corrected image is used to generate the one or more filters, and not the original image of the specimen, which has been used at the first iteration of operation 310 to generate the first filters. Operation 320 is then repeated, in which the original image of the specimen is compared to the one or more (new) filters. This comparison enables identifying a (new) set of points (operation 330). This (new) set of points corresponds to a second estimate of the position of the edge of the structural element of the specimen in the image.

If necessary, the method can be repeated once again. In this case, the method further includes repeating operation 340, which includes determining, for each row of the image, a distance between the point of the row and a reference line formed by the set of points (operation 340), and moving the rows of the original image to generate a new corrected image (operation 350). As mentioned above, this can be performed equivalently for the columns. The method then reverts once again to operation 310 at which one or more new filters can be generated based on the new corrected image.

The method can be repeated until a criterion is met. Different criteria can be used. In some examples, the method is repeated until a certain number of iterations has been reached. In some examples, the method is repeated until the filter generated at iteration N, and the filter generated at iteration N−1 , match. The two filters can be considered as matching when a matching criterion is met. The matching between the two filters can be assessed using any adapted method, such as a comparison method, a cross-correlation method, etc. In some examples, the method is repeated until the difference between the position of the set of points at iteration N of the method, and the position of the set of points at iteration N−1 of the method, is below a threshold. These examples are not limitative, and other criteria can be used.

FIG. 12B also describes an iterative method, which is a variant of the method of FIG. 12A. The method of FIG. 12A includes operations 300 to 350₁ already described above with reference to FIG. 3C. At operation 350₁, the corrected image is generated. Then, it is reverted to operation 310₁, in which a filter (new filter) is generated. At this iteration, the corrected image is used to generate the new filter, and not the original image of the specimen, which has been used at the first iteration of operation 310₁ to generate the first filter(s). Operation 320₁ is then repeated, in which each row of the original image of the specimen is compared to the new filter. This enables generating a score map, which is used to identify a new set of points (operation 330₁). This new set of points corresponds to a second estimate of the position of the edge of the structural element of the specimen in the image. If necessary, the method can be repeated once again, by determining, for each row of the image, a distance between the point of the row and a reference line formed by the set of points (operation 340₁) and moving the rows of the original image to generate a new corrected image (operation 350₁). The method then reverts to operation 310₁ at which a new filter can be generated based on the new corrected image. The method can be repeated until a criterion is met. Examples of criteria have been provided above and can be used herein.

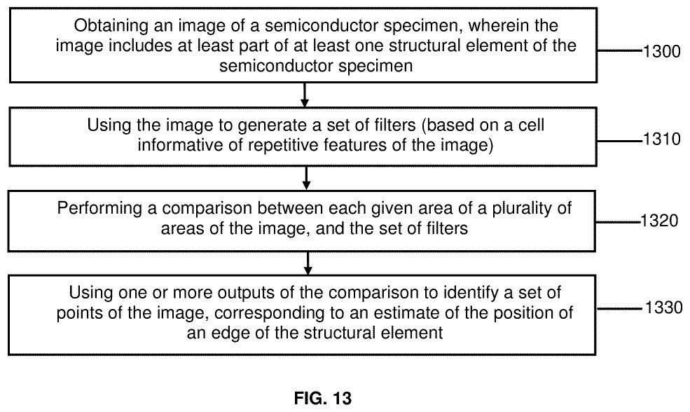

Attention is now drawn to FIG. 13, which describes another method of estimating the position of one or more edges in an image of the specimen, based on the usage of a plurality of filters.

The method of FIG. 13 includes obtaining (operation 1300) at least one image of a semiconductor specimen. The image includes at least part of a structural element of the specimen, which is associated with an edge to be detected. The image has been acquired by an examination tool (see 101, 102 in FIG. 1) such as an electron beam examination tool (SEM). In some examples, the image is generated by isolating the edge to be detected from an image acquired by the examination tool.

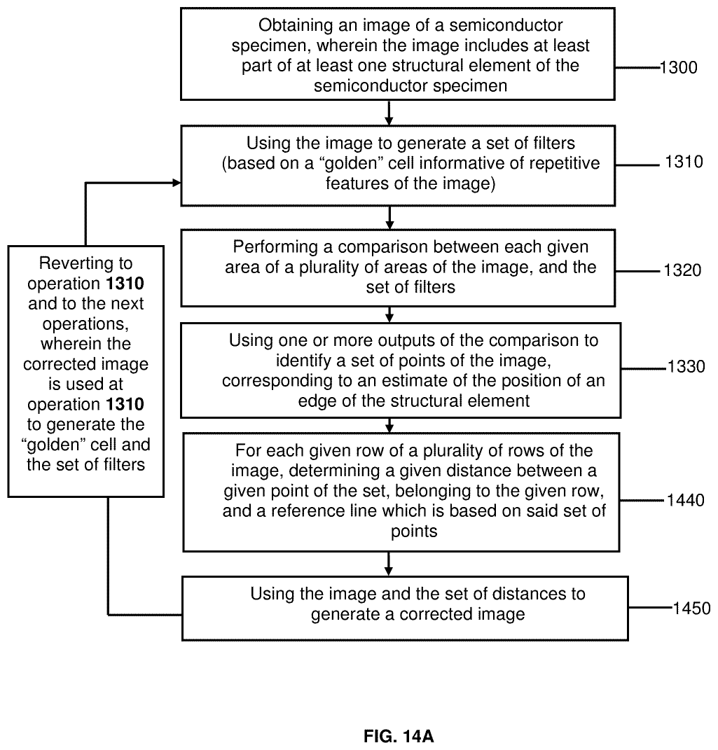

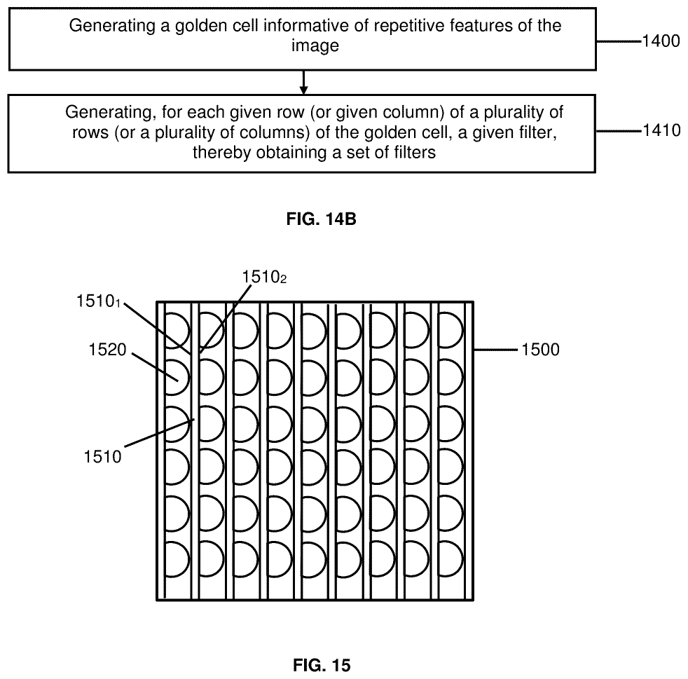

The method of FIG. 13 further includes using (operation 1310) the image to generate a set of filters, including a plurality of filters. In some examples, and as depicted in FIG. 14B, this can include generating (operation 1400) a cell (hereinafter termed a golden cell) representative of the image. The golden cell can correspond to an average of the pixel intensity of representative features of the image. The representative features can correspond to repetitive features of the image. For each given row (or given column) of a plurality of rows (or of a plurality of columns) of the golden cell, a given filter is generated, thereby obtaining a set of filters. Each respective filter can correspond to the evolution of the pixel intensity profile of the respective row of the golden cell along the row axis (or of the respective column along the column axis).

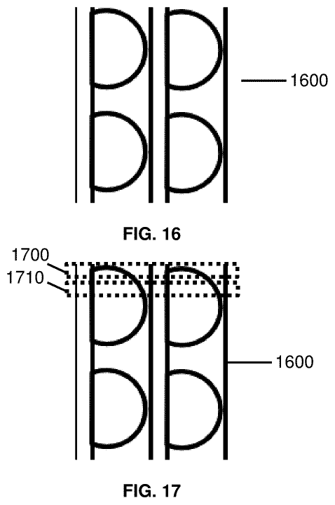

A non-limitative example of the generation of a golden cell is provided in FIGS. 15 and 16. FIG. 15 depicts an image 1500 of a specimen. The specimen includes at least two layers: the upper layer includes electrical conductors 1510, each including two lateral edges 1510₁, 1510₂ to be detected, and the bottom layer includes repetitive structural elements 1520 (generating repetitive patterns in the image 1500). The method of FIG. 13 can be used to detect edges in an image of a specimen including a plurality of layers, such as, but not limited to, the specimen of FIG. 15. Note that the method of FIG. 13 can be used also to detect edges in an image of a specimen including a single layer.

FIG. 16 depicts a golden cell 1600 generated based on the image 1500 of the specimen depicted in FIG. 15. As visible in FIG. 16, the golden cell 1600 includes a sample informative of the repetitive features present in the image 1500. It can be generated by averaging the pixel intensity profile of the repetitive features present in the image of the specimen.

FIG. 17 depicts a set of filters generated based on the golden cell 1600. The first filter of the set corresponds to the pixel intensity profile of the first row 1700 of the golden cell 1600, the second filter of the set corresponds to the pixel intensity profile of the second row 1710 of the golden cell 1600, etc.

In some examples, the set of filters can be generated by feeding the image of the specimen to a machine learning model (such as machine learning model 113), which has been trained using supervised learning to generate the set of filters based on an input image of a specimen. During the training, the machine learning model is fed with training images of a specimen. Each training image is associated with a label corresponding to a set of filters associated with the training image.

The method of FIG. 13 further includes performing (operation 1320) a comparison between each given area of a plurality of areas of the image, and the set of filters. This comparison can include, for each given area: comparing the first row of the given area with the first filter of the set, comparing the second row of the given area with the second filter of the set, etc. In other words, for a given area including N rows R₁ to R_{N}, and a set of filters including N filters F₁ to F_{N}, row number R₁ is compared to filter F₁, with I from 1 to N.

In this case, each row (or each column) of the given area is compared with a filter of the set of filters, associated with a row (or a column) with a position relative to the golden cell corresponding to a position of said row or said column relative to the given area. For example, the first row of the given area can be compared with the filter generated based on the first row of the golden cell. Note that this is not limitative, and additional and/or different comparisons can be performed between each given area and the set of filters.

Once each row of the given area has been compared with the corresponding filter of the set, the next given area is compared to the set of filters. The next given area can correspond to the area located below the previous given area (or above the previous given area), along the vertical axis of the image. This is however not limitative. The dimensions of each given area can be selected to match the dimensions of the golden cell.

The comparison indicates to which extent the pixel intensity distribution of each given area matches the pixel intensity distribution of the set of filters. Various methods can be used to perform this comparison, such as (but not limited to), cross-correlation, normalized cross correlation, least square method, etc.

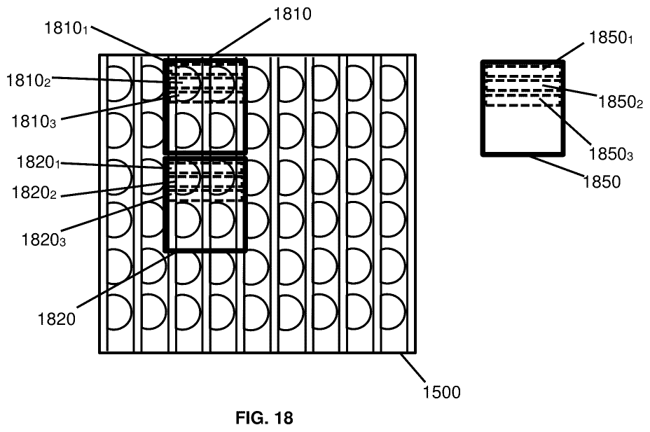

A non-limitative example is illustrated in FIG. 18, in which the first area 1800 of the image is compared to the set 1850 of filters. In particular, the first row 1810₁ of the first area 1800 is compared to the first filter 1850₁ (generated based on the first row of the golden cell), the second row 1810₂ of the first area 1800 is compared to the second filter 1850₂ (generated based on the second row of the golden cell), the third row 1810₃ of the first area 1800 is compared to the third filter 1850₃ (generated based on the third row of the golden cell), etc. Once all rows of the first area 1800 have been compared with the set 1850 of filters, the next area (second area 1820) is processed. In particular, the first row 1820₁ of the second area 1820 is compared to the first filter 1850₁, the second row 1820₂ of the second area 1820 is compared to the second filter 1850₂, the third row 1820₃ of the second area 1820 is compared to the third filter 1850₃, etc.

Note that in some other examples, the set of filters has been generated by projecting the pixel intensity of the golden cell along the row axis (horizontal axis). In this case, each column of the given area is compared to the corresponding filter.

The method of FIG. 13 further includes using (operation 1330) one or more outputs of the comparison to identify a set of points of the image.

The comparison enables assigning a score to each of a plurality of pixels of the image. Note that a score can be assigned to one or more sub-pixels of the image (points located between the pixels) by interpolating the scores of the adjacent pixels, or by using a parabola. A score map is therefore obtained. Each score indicates the level of matching between the pixel intensity at this location, and the corresponding pixel intensity of the filter(s). For example, a high score indicates a high level of matching, and a low score indicates a low level of matching.

At least one given point can be identified based on the score map. In particular, for each given row, the given point can be selected as the pixel (or sub-pixel) of the given row with the highest score. A set of points is therefore obtained. As mentioned above, it can occur that the comparison is performed between the columns of the image and the filter(s). In this case, the points are identified along the column axis.

The points of the set constitute a first estimate of the position of the edge of the structural elements of the specimen present in the image.

In some examples, it is possible to ignore certain points. The points which are located at a distance from the average position of the set of points above a threshold, and/or at a distance which differs significantly from the distance of the other points from the average position of the set of points, can be ignored. This has been described above with reference to FIG. 8.

In some examples, if, for a given row, the given point associated with the highest score is such that its score is significantly below the scores of the other points of the set, it can be ignored. For example, assume that the score in the score map is on a scale between −1 and +1. Assume that most points (corresponding to the highest score per row or column) have a score between 0.8 and +1. Assume that a given point has a score equal to +0.2. This given point can be ignored and will not be part of the set of points.

Note that this method can be used to estimate the position of curved edges, or of edges with various different shapes. This will be also discussed with reference to FIGS. 28 and 29.

Attention is now drawn to FIG. 14A, which depicts a variant of the method of FIG. 13, in which an iterative process is used to estimate the position of the edge.

The method of FIG. 14A includes operations 1300 to 1330 already described with reference to FIG. 13.

The method of FIG. 14A further includes (operation 1440), for each given row of a plurality of rows of the image, determining a given distance between a given point of the set, belonging to the given row, and a reference line which is based on said set of points. The reference line can correspond to the average position of the set of points along the row axis. This enables obtaining a set of distances (one per row, or one per column). Operation 1440 is similar to operations 340 and 340₁ described above.

The method of FIG. 14A further includes using (operation 1450) the image and the set of distances to generate a corrected image. In particular, each row can be translated by the distance of the set of distances computed for this row. Operation 1450 is similar to operations 350 and 350₁ described above.

In the corrected image, the set of points is substantially aligned along a line, as explained with reference to FIG. 11.

Then, it is reverted to operation 1310, in which a new set of filters is generated. At this iteration, the corrected image is used to generate the golden cell and the new set of filters, and not the original image of the specimen (which has been used at the first execution of operation 1310 to generate the first set of filters). Operation 1320 is then repeated, in which each area of a plurality of areas of the original image of the specimen is compared to the set of filters. This comparison enables identifying a (new) set of points (operation 1330). This new set of points corresponds to a second estimate of the position of the edge of the structural element of the specimen in the image. If necessary, the method can be repeated once again, by determining, for each row of the image, a distance between the point of the row and a reference line formed by the new set of points (operation 1340) and moving the rows of the original image to generate a new corrected image (operation 1350). The method then reverts to operation 1310 at which one or more filters can be generated based on the new corrected image.

The method can be repeated until a criterion is met. Different criteria can be used. In some examples, the method is repeated until a certain number of iterations has been reached. In some examples, the method is repeated until the filter generated at iteration N and the filter generated at iteration N−1 match. The two filters can be considered as matching when a matching criterion is met. The matching between the two filters can be assessed using any adapted method, such as a comparison method, a cross-correlation method, etc. In some examples, the method is repeated until the difference between the position of the points at iteration N of the method, and the position of the points at iteration N−1 of the method, is below a threshold. These examples are not limitative, and other criteria can be used.

Note that this method can be used to estimate the position of curved edges, or of edges with various different shapes. This will be also discussed with reference to FIGS. 28 and 29.

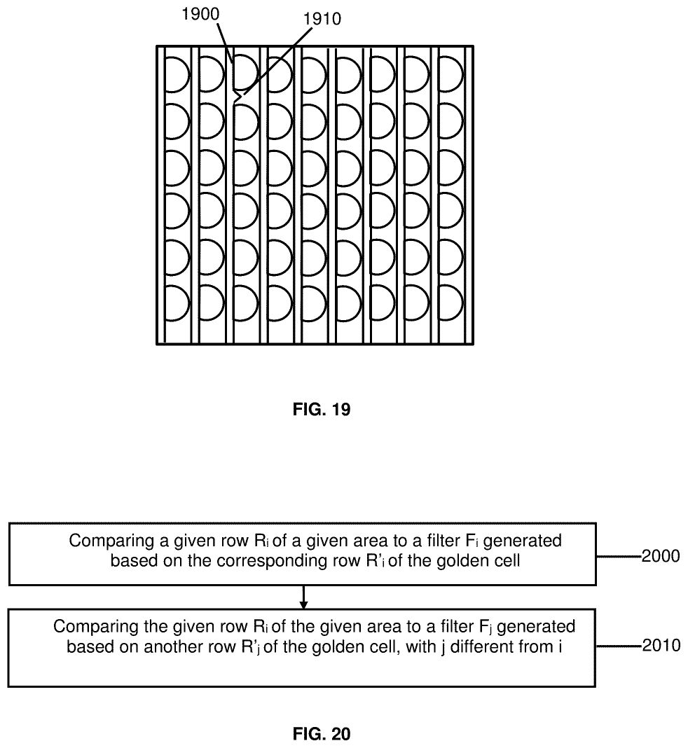

### Attention Is Now Drawn to FIG. 19.

One or more edges of the specimen may be associated with process variation (PV). A non-limitative example is illustrated in FIG. 19, in which edge 1900 is associated with process variation 1910. In this case, it is expected that the corresponding filter generated based on the golden cell will not match the image at this location. Various methods are proposed hereinafter, which may be used to overcome this problem. These methods can be used even in the absence of process variation, for other purposes.

Attention is now drawn to FIGS. 20A and 20B.

Assume that a given area has to be compared to a set of filters, generated based on a golden cell (or using other techniques, such as by using a machine learning model). In some examples, a row of the given area may be compared not only to the filter generated based on the corresponding row in the golden cell (operation 2000), but also to one or more filters generated based on other rows in the golden cell (operation 2010).

For example, assume that the given area includes N rows R₁ to R_{N}, and that the golden cell includes N rows R'₁ to R'_{N}, from which N filters F₁ to F_{N} have been generated.

The row R₁ of the given area can be compared not only with the filter F₁, but also with other filters Fⱼ, with j different from i. For example, the row Rᵢ can be compared to the filter Fᵢ, and also to the next filter Fᵢ₊₁ and to the previous filter Fᵢ₊₁.

In some examples, the row Rᵢ is compared to different filters Fⱼ (with j different from i) of the set of filters. The output of the comparison which indicated the best match (among all comparisons performed for this row) is used to generate the score of the pixels of this row and is stored in the score map. In some examples, the comparison is stopped when the score obtained at the current comparison is higher than the score obtained at the previous comparison (which indicates that a better match has been found).

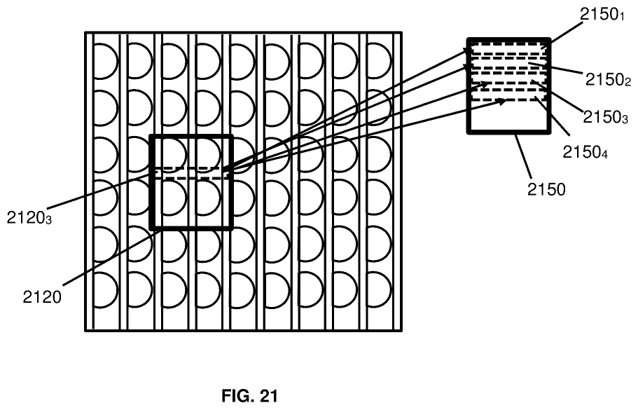

A non-limitative example is illustrated in FIG. 21, in which the third row 2120₃ of the given area 2120 of the image is compared not only to the filter generated based on the third row 2150₃ of the golden cell 2150, but also to the filter generated based on the first row 2150₁ of the golden cell 2150, to the filter generated based on the second row 2150₂ of the golden cell 2150 and to the filter generated based on the fourth row 2150₄ of the golden cell 2150. Note that this is only an example, and the comparison can be based on different filters of the set, and/or based on a different number of filters of the set.

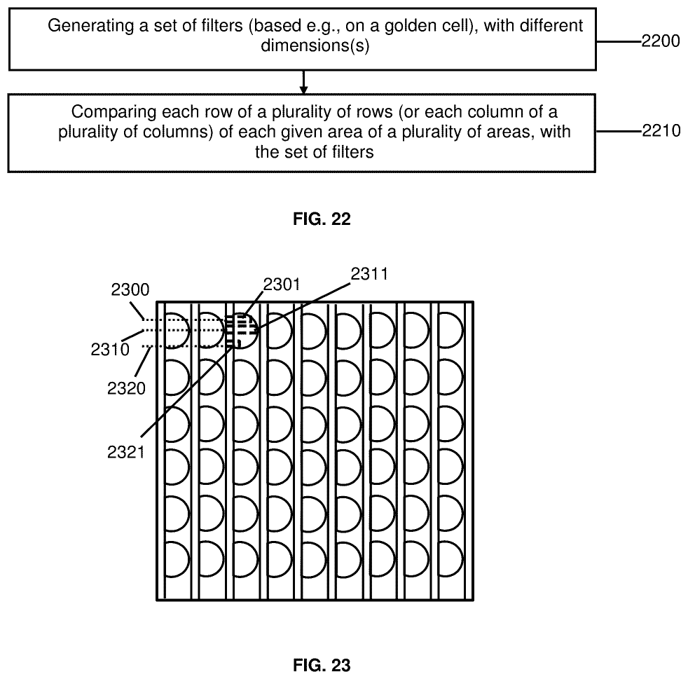

Attention is now drawn to FIG. 22, which depicts another method of generating a set of filters.

In this method, the set of filters is generated such that one or more of the dimensions of the filters of the set are not constant but are rather variable within the set of filters (operation 2200). In other words, if the set of filters include filters F₁ to F_{N}, each filter Fᵢ has a different dimension that one or more other filters Fⱼ of the set, with j different from i. In some examples, the dimension of the filters of the set is not constant along the row axis (horizontal axis). The filters of the set can be generated based on a golden cell, as explained above. However, the dimension(s) of the filters is/are varied. Then, each given area of a plurality of areas of the image is compared to the set of filters (operation 2210), as explained above.

In some examples, the dimensions of the filters of the set along the row axis (or along the column axis) depend on the position of one or more structural elements of the specimen.

Assume that the specimen includes at least two layers: a first layer (top layer) includes one or more edges (of one or more first structural elements) to be detected, and a second layer (bottom layer, located underneath the first layer) includes one or more second structural elements. At each row, the dimension of the filter can be such that it ends at an edge of a second structural element of the second layer. In particular, at each row, the dimension of the filter can be such that it extends up to the end of a second structural element of the second layer.

Since the edges of the second structural elements do not have a constant position along the column axis of the image (vertical axis of the image—see e.g., FIG. 15), the dimensions of the filters along the row axis is not constant within the set. A non-limitative example is provided in FIG. 23. For row 2300, a filter with the dimension along the row axis of reference 2301 is used. For row 2310, a filter with the dimension along the row axis of reference 2311 is used, which has a longer dimension than the filter 2301 along the row axis. For row 2320, the filter with the dimension of reference 2323 along the row axis is used, which has a smaller dimension than filter 2301 and than filter 2311.

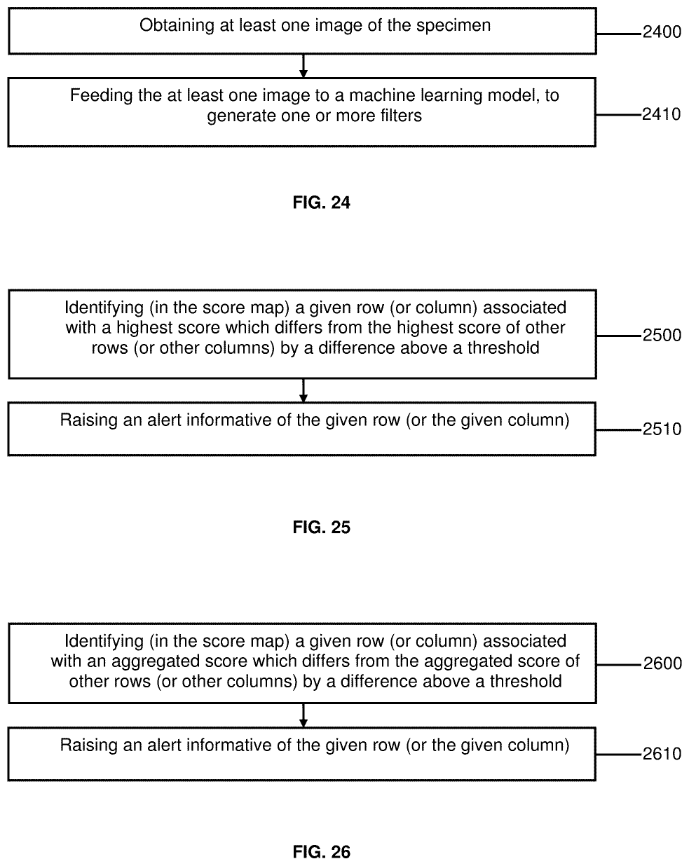

Attention is now drawn to FIG. 24, which depicts a method of generating a filter using a machine learning model 113.

As mentioned in the various methods above, one or more filters are generated based on the pixel intensity of at least one image of a specimen.

The method includes obtaining (operation 2400) at least one image of the specimen. The method further includes feeding (operation 2410) the image to a machine learning model 113, to generate one or more filters.

In some examples, the machine learning model 113 has been trained to generate a single filter for the whole image fed to the machine learning model 113. This can be used e.g., in the method of FIG. 3B.

In some examples, the machine learning model 113 has been trained to generate, for a given image, a plurality of filters. This can be used e.g., in the method of FIG. 14A.

Training of the machine learning model 113 can include feeding the machine learning model 113 with a training set of training images, each training image being informative of a part of a specimen including one or more edges of structural elements (electrical lines, gates, transistors, etc.). In the training set, each training image is associated with a label, corresponding to one or more filters.

In some examples, the filter stored in the label corresponds to the average of the pixel intensity of the training image along the rows or along the columns.

In some other examples, a golden cell is generated based on the training image, which corresponds to a cell informative of repetitive features of the training image. As mentioned above, this cell can be obtained by averaging the pixel intensity of repetitive features in the training image. Each row (or column) of the golden cell is used to generate a different filter, corresponding e.g., to the pixel intensity profile of the row (or column).

In some examples, the filter(s) stored in the label has (have) been generated using simulation data and/or experimental data.

Attention is now drawn to FIG. 25.

As explained with reference to the various methods described above, a score map can be generated, which indicates, for each pixel (or sub-pixel), the level of matching between its pixel intensity and the corresponding pixel intensity of the filter(s). For each row, or each column, one or more points can be identified, which are associated with the highest score for this row.

In other words, each row (or column) Rᵢ is associated with a corresponding highest score Sᵢ (within the row or within the column) in the score map.

In the method of FIG. 25, it can be identified that the highest score Sₖ of a given row Rₖ significantly differs from the highest score of the other rows (operation 2500). This can be indicative of the presence of a defect in the given row Rₖ. Responsive to this identification, an alert can be raised (operation 2510), which indicates that a defect is or may be present in this given row. The defect can correspond e.g., to a short-circuit, a bridge, an absence of an electrical line, or other defects. The alert can also include the number and/or the position of the given row Rₖ.

In some examples, when a difference between the highest score of a given row and the highest score of one or more other rows is above a threshold, the alert can be raised. The threshold can be set in advance and/or can be set or modified by an operator of the system. In some examples, when a difference between the highest score of a given row and the average highest score of all rows is above a threshold, the alert can be raised.

Attention is now drawn to FIG. 26.

For each row Rᵢ (or each column) of the score map, an aggregated score ASᵢ can be computed. For example, the aggregated score corresponds to the average score along each row (or each column).

The method of FIG. 26 further includes identifying whether a given row Rₖ is associated with an aggregated score ASₖ which significantly differs from the highest score of the other rows (operation 2600). This can be indicative of the presence of an anomaly in the given row Rₖ. Responsive to this identification, an alert can be raised (operation 2610), which indicates that an anomaly is or may be present in this given row. The anomaly can correspond e.g., to a short-circuit, or an absence of a line, or other anomalies. The alert can also include the number and/or the position of the given row Rₖ.

In some examples, when a difference between the aggregated score ASₖ of a given row Rₖ and the aggregated score of one or more other rows is above a threshold, the alert can be raised. The threshold can be set in advance and/or can be set or modified by an operator of the system.

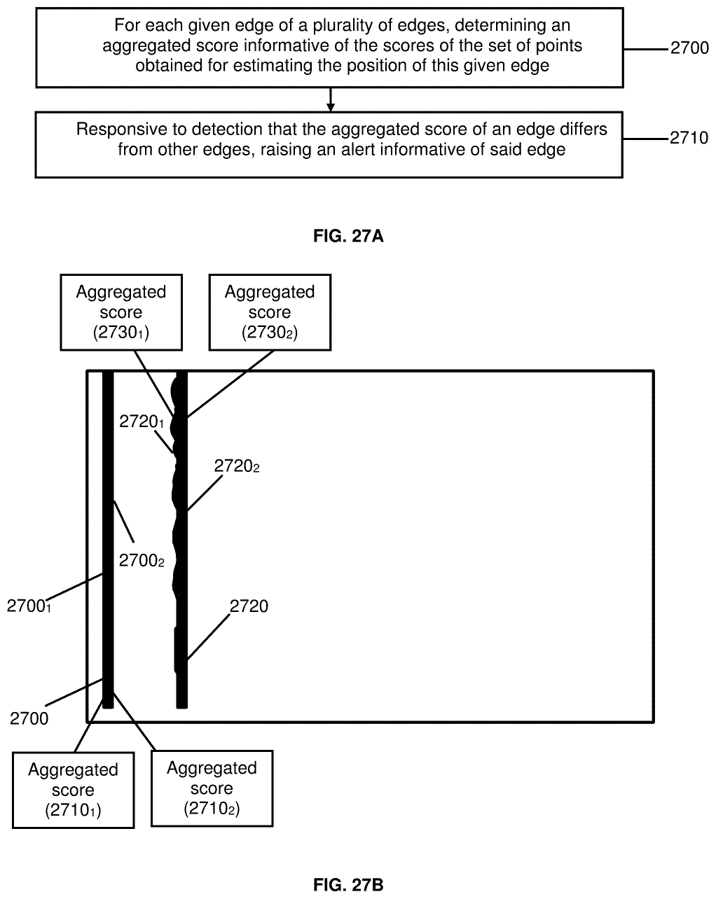

### Attention Is Now Drawn to FIG. 27a.

Assume that the specimen includes a plurality of edges, belonging to different structural elements, and/or to the same structural elements of the specimen.

The various methods described herein can be used to detect the position of these edges. As mentioned above, detection of each edge involves determining a set of points, each associated with a score (e.g., highest score per row or per column). The set of points is an estimate of the position of the edge.

In some examples, for each edge, data informative of an aggregated score can be computed (operation 2700), based on the scores of the different points of the set. For example, for each edge, the average score of the set of points is computed. If the aggregated score of a given edge differs (with a difference above a threshold) from the aggregated scores of other edges, an alert can be raised, which indicates that a defect may be present in the given edge (operation 2710).

A non-limitative example is illustrated in FIG. 27B. A plurality of aggregated scores is computed: aggregated score 2710₁ for the left edge 2700₁ of the electrical line 2700, aggregated score 2720₂ for the right edge 2700₂ of the electrical line 2700, aggregated score 2730₁ for the left edge 2720₁ of the electrical line 2720, aggregated score 2730₂ for the right edge 2720₂ of the electrical line 2720. If one of the aggregated scores significantly differs from the other aggregated scores, this can be indicative of the presence of a defect in the corresponding edge.

In other examples, the distribution of scores of the different points of the set is computed for each edge. If the distribution associated with a given edge differs (with a difference above a threshold) from the distributions associated with other edges, an alert can be raised, which indicates that a defect may be present in the given edge. This can include comparing values such as variance, median, average, etc. between the different distributions.

Attention is now drawn to FIG. 28.

Assume that the specimen includes a plurality of edges, belonging to different structural elements, and/or to the same structural elements of the specimen.

The various methods described herein can be used to detect the position of these edges. As mentioned above, detection of each edge involves determining one or more filters. Assume that for each edge, one or more filters have been generated. If an iterative method has been used to determine the position of each edge (see e.g. FIGS. 3B, 3C, 12A, 12B, 14A) the one or more filters can correspond to the or more filters obtained at the last iteration of the method. The method of FIG. 28 includes obtaining (operation 2800) for each edge, the corresponding filter(s).

The method of FIG. 28 includes performing (operation 2810) a comparison between the different filters obtained for the different edges of the image. The comparison can rely on cross-correlation, or other comparison methods.

The method of FIG. 28 furthers includes using (operation 2820) this comparison to determine whether a defect is present in one or more of the different edges. If, for a given edge, the corresponding filter substantially differs from the filters of other edges, an alert can be raised, informative of a suspected defect in this given edge. The alert can include the position of the given edge.

In the various methods described above, it is possible to determine the position of a plurality of edges. The various methods can be used to detect edges with different profiles. In some examples, the various methods can be used to determine the position of edges which are substantially straight (including possible defects, such as process variation). The various methods can be also used to determine the position of curved or circular edges (such as edges of a contact), or edges with other profiles corresponding to any shape.

In some examples, pre-processing operations can be performed on the image of the element acquired by the examination tool, in order to convert the image of the element into a matrixial representation (also called strip matrix). In this matrixial representation, each line of the representation is informative of the position of a different point along the contour (or equivalently the edges) of the element. The representation includes a plurality of lines informative of pixel intensity in the image along a plurality of axes of the structural element, associated with different orientations, as further discussed with reference to FIG. 31.

This method is illustrated in FIG. 29 and includes converting (operation 2900) the image of an element into a matrixial representation. Once this matrixial representation has been obtained, it can be processed (operation 2910) according to one or more of the various methods described above, which enables estimating the position of a set of points belonging to the contour of the element. Once the positions of the points of the set have been determined in the referential of the matrixial representation, these positions can be converted back (operation 2920) into the referential of the image. An estimate of the position of the contour (or equivalently of the edges) of the element in the image is therefore obtained.

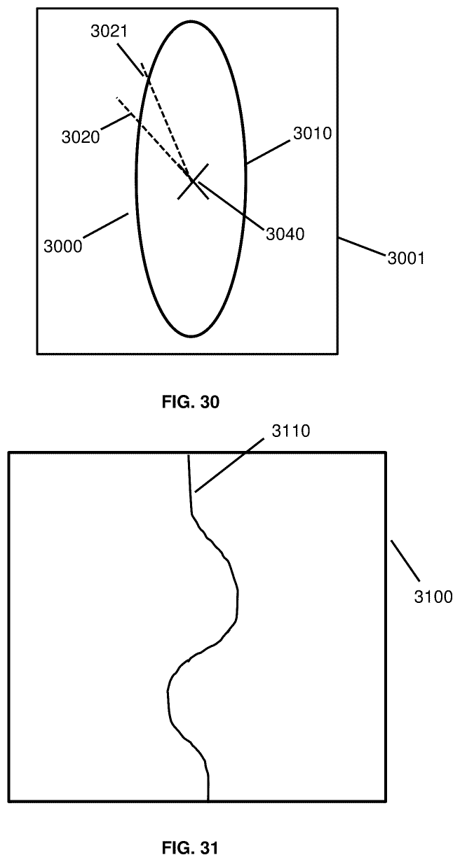

FIG. 30 illustrates an example of an image 3001 of an element 3000, associated with a contour 3010 constituting the edges of the element 3000. In compliance with the method of FIG. 29, the contour 3010 of the element 3000 is converted into a matrixial representation 3100, visible in FIG. 31. The set of points 3110 corresponds to the contour 3010. This conversion can be performed as described with reference to FIG. 32. The approximate position of the center of mass 3040 of the element 3000 is determined (operation 3200), for example based on CAD data. Then, a plurality of axes (see 3020, 3021, etc.), with different angular orientations, is traced from the center of mass 3040 over 360 degrees (operation 3210). Each axis contains a point (single point) of the contour. The matrixial representation 3100 corresponds to the aggregation of the different axes into a single representation (transformation from a shape to a matrixial representation), in which each line is of the matrixial representation 3100 corresponds to an axis of the plurality of axes (operation 3220). The matrixial representation 3100 is then processed according to the various methods described above. This enables determining the position of the set of points 3110. An inverse transformation (transformation from a matrixial representation to a shape) is performed on the set of points 3110 in order to obtain the estimate of the position of the contour (edges) in the referential of the image.

In the detailed description, numerous specific details have been set forth in order to provide a thorough understanding of the disclosure. However, it will be understood by those skilled in the art that the presently disclosed subject matter may be practiced without these specific details. In other instances, well-known methods, procedures, components, and circuits have not been described in detail so as not to obscure the presently disclosed subject matter.

Unless specifically stated otherwise, as apparent from the aforementioned discussions, it is appreciated that throughout the specification discussions utilizing terms such as “obtaining”, “performing”, “comparing”, “determining”, “using”, “outputting”, “training”, “feeding”, “generating”, or the like, refer to the action(s) and/or process(es) of a computer that manipulate and/or transform data into other data, said data represented as physical, such as electronic, quantities and/or said data representing the physical objects.

The terms “computer” or “computer-based system” should be expansively construed to include any kind of hardware-based electronic device with a data processing circuitry (e.g., digital signal processor (DSP), a GPU, a TPU, a field programmable gate array (FPGA), an application specific integrated circuit (ASIC), microcontroller, microprocessor etc.), including, by way of non-limiting example, the computer-based system 103 of FIG. 1 and respective parts thereof disclosed in the present application. The data processing circuitry (designated also as processing circuitry) can comprise, for example, one or more processors operatively connected to computer memory, loaded with executable instructions for executing operations, as further described below. The data processing circuitry encompasses a single processor or multiple processors, which may be located in the same geographical zone, or may, at least partially, be located in different zones, and may be able to communicate together. The one or more processors can represent one or more general-purpose processing devices such as a microprocessor, a central processing unit, or the like. More particularly, a given processor may be one of: a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

It is to be noted that while the present disclosure refers to the processing circuitry 104 (or 130) being configured to perform various functionalities and/or operations, the functionalities/operations can be performed by the one or more processors of the processing circuitry 104 in various ways. By way of example, the operations described hereinafter can be performed by a specific processor, or by a combination of processors. The operations described hereinafter can thus be performed by respective processors (or processor combinations) in the processing circuitry 104, while, optionally, at least some of these operations may be performed by the same processor. The present disclosure should not be limited to be construed as one single processor always performing all the operations.

The term “specimen” used in this specification should be expansively construed to cover any kind of wafer, masks, and other structures, combinations and/or parts thereof used for manufacturing semiconductor integrated circuits, magnetic heads, flat panel displays, and other semiconductor-fabricated articles.

The term “examination” used in this specification should be expansively construed to cover any kind of metrology-related operations as well as operations related to detection and/or classification of defects in a specimen during its fabrication. Examination is provided by using non-destructive examination tools during or after manufacture of the specimen to be examined. By way of non-limiting example, the examination process can include runtime scanning (in a single or in multiple scans), sampling, reviewing, measuring, classifying and/or other operations provided with regard to the specimen or parts thereof using the same or different inspection tools. Likewise, examination can be provided prior to manufacture of the specimen to be examined, and can include, for example, generating an examination recipe(s) and/or other setup operations. It is noted that, unless specifically stated otherwise, the term “examination”, or its derivatives used in this specification, is not limited with respect to resolution or size of an inspection area. A variety of non-destructive examination tools includes, by way of non-limiting example, scanning electron microscopes, atomic force microscopes, optical inspection tools, etc.

By way of non-limiting example, run-time examination can employ a two-phase procedure, e.g., inspection of a specimen followed by review of sampled locations of potential defects. During the first phase, the surface of a specimen is inspected at high-speed and relatively low-resolution. In the first phase, a defect map is produced to show suspected locations on the specimen having high probability of a defect. During the second phase, at least some of the suspected locations are more thoroughly analyzed with relatively high resolution. In some cases, both phases can be implemented by the same inspection tool, and, in some other cases, these two phases are implemented by different inspection tools.

The term “defect” used in this specification should be expansively construed to cover any kind of abnormality or undesirable feature/functionality formed on a specimen.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately, or in any suitable sub-combination. In the detailed description, numerous specific details are set forth in order to provide a thorough understanding of the methods and apparatus.

In embodiments of the presently disclosed subject matter, fewer, more, and/or different stages than those shown in the methods of FIGS. 3A, 3B, 3C, 12A, 12B, 13, 14A, 14B, 20, 22, 24, 25, 26, 27A, 28, 29 and 32 may be executed. In embodiments of the presently disclosed subject matter, one or more stages illustrated in the methods of FIGS. 3A, 3B, 3C, 12A, 12B, 13, 14A, 14B, 20, 22, 24, 25, 26, 27A, 28, 29 and 32 may be executed in a different order, and/or one or more groups of stages may be executed simultaneously.

It is to be understood that the invention is not limited in its application to the details set forth in the description contained herein or illustrated in the drawings.

It will also be understood that the system according to the invention may be, at least partly, implemented on a suitably programmed computer. Likewise, the invention contemplates a computer program being readable by a computer for executing the method of the invention. The invention further contemplates a non-transitory computer-readable memory tangibly embodying a program of instructions executable by the computer for executing the method of the invention.

The invention is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the invention as hereinbefore described without departing from its scope, defined in and by the appended claims.

What is claimed is

1. A system comprising one or more processing circuitries configured to:
obtain an image informative of at least part of at least one structural element of a semiconductor specimen,
use the image to generate one or more filters,
perform a comparison between:
each given area of a plurality of areas of the image, and
the one or more filters,
and
determine, based on the comparison, a set of points of the image, informative of an estimated position of at least one edge of the at least one structural element in the image, the set of points comprising, for each given row of a plurality of rows of the image, or for each given column of a plurality of columns of the image, at least one given point of the given row or of the given column of the image.

2. The system of claim 1, wherein (i) or (ii) is met:
(i) for said each given row or said each given column, the given point corresponds to the comparison indicative of a best match within said each given row or said each given column;
(ii) the comparison enables outputting a set of scores, wherein, for said each given row or for said each column, a given score of the given point is the highest among scores of points of the said each given row or of the said each given column.

3. The system of claim 1, wherein using the image to generate the one or more filters comprises at least one of (i) or (ii):
(i) averaging pixel intensity along rows or columns of the image;
(ii) using a machine learning model and the image to generate the one or more filters.

4. The system of claim 1, configured to:
for each given row of a plurality of rows of the image, or for each column of a plurality of columns of the image, determine a given distance between:
the given point belonging to the given row or to the given column, and
a reference line which is based on said set of points,
thereby obtaining a set of distances,
use the image and the set of distances to generate a corrected image, and
use the corrected image to determine another estimate of the position of the at least one edge in the image.

5. The system of claim 1, configured to:
for each given row of a plurality of rows of the image, or for each given column of a plurality of columns of the image:
determine a given distance between the given point belonging to the given row or to the given column, and a reference line which is based on said set of points,
use the given distance to perform a displacement of said each given row or of said each given column, wherein the given distance differs between at least two rows or two columns of the image,
thereby obtaining a corrected image,
and
use the corrected image to determine another estimate of the position of the at least one edge in the image.

6. The system of claim 1, configured to perform at least one of (i) or (ii):
(i) determining at least one point of the set of points located at a distance from an average position of the set of points above a first threshold;
(ii) determining at least one point of the set of points located at a distance from an average position of the set of points which differs from a distance of other points of the set of points to said average position, by a second threshold.

7. The system of claim 1, wherein each point of the set of points is associated with a score obtained based on said comparison, wherein the system is configured to:
identify a point of the set of points, which is associated with a score which differs from scores of other points of the set, or from an aggregated score of the set, by a threshold,
and
raise an alert informative of said point, or of a row or a column comprising said point.

8. The system of claim 1, wherein, the comparison enables generating a set of scores, wherein the system is configured to:
identify a given row, or a given column of the image, associated with an aggregated score informative of various scores within said given row or said given column, which differs from aggregated scores of other rows, or other columns, of the image, by a difference above a threshold,
and
raise an alert informative of said given row or said given column.

9. The system of claim 1, configured to:
estimate a position of different edges based on different filters,
perform a comparison between the different filters, and
use this comparison to determine whether a defect is present in one or more of said different edges.

10. The system of claim 1, configured to:
obtain an initial image comprising a plurality of edges of one or more structural elements,
split the initial image into a plurality of images, each including a different given edge of the plurality of edges,
for each given image of the plurality of images:
use the given image to generate one or more given filters,
perform a comparison between each given area of a plurality of areas of the given image and the one or more filters, and
determine, based on the comparison, a given set of points of the given image, informative of an estimated position of the given edge in the given image, the given set of points comprising, for each given row of a plurality of rows of the given image, or for each given column of a plurality of columns of the given image, at least one given point of the given row or of the given column of the given image.

11. The system of claim 1, configured to:
use the image to generate a set of filters,
perform a comparison between:
each given area of a plurality of areas of the image, and
the set of filters,
and
use said comparison to determine the set of points of the image, informative of an estimated position of the edge.

12. The system of claim 11, configured to generate a cell informative of repetitive features of the image, and to use the cell to generate the set of filters.

13. The system of claim 11, configured to perform a comparison between each respective row, or each respective column, of the given area, with a respective filter of the set of filters.

14. The system of claim 11, configured to:
(1) for a current area of the plurality of areas, perform a comparison between each respective row, or each respective column, of the current area, with a respective filter of the set of filters,
(2) when all rows, or all columns of the current area, have been compared, repeat (1) for a next area of the plurality of areas, different from the current area.

15. The system of claim 12, configured to perform a comparison between each given row, or each given column, of the given area, with a filter of the set of filters, associated with a row, or a column, of the cell, which has a position relative to the cell corresponding to a position of said given row or said given column relative to the given area.

16. The system of claim 12, configured to perform a comparison between each given row, or each given column, of the given area, with:
a filter of the set of filters, associated with a row, or a column, of the cell, with a position relative to the cell corresponding to a position of said given row or said given column relative to the given area, and
at least another filter of the set of filters, associated with a row, or a column, of the cell, with a position relative to the cell which differs from the position of said given row or said given column relative to the given area.

17. The system of claim 1, wherein (i) or (ii) is met:
(i) the one or more filters comprise a set of filters, wherein the system is configured to use the image to generate the set of filters with different dimensions among filters of the set;
(ii) the one or more filters comprise a set of filters, wherein the system is configured to use the image to generate the set of filters with different dimensions among filters of the set, wherein the structural element is located in a first layer of the specimen, wherein, for at least one filter of the set of filters, a dimension of said at least one filter depends on a position of one or more other structural element of the specimen, located in a second layer of the specimen, different from the first layer.

18. The system of claim 1, configured to:
obtain an initial image of the structural element acquired by an examination tool, and
convert the initial image into the image informative of the at least part of the structural element, wherein the image includes a plurality of lines informative of pixel intensity along different axes of the initial image, associated with different orientations.

19. A computer-implemented method comprising:
obtaining an image informative of at least part of at least one structural element of a semiconductor specimen,
using the image to generate one or more filters,
performing a comparison between:
each given area of a plurality of areas of the image, and
the one or more filters,
and
determining, based on the comparison, a set of points of the image, informative of an estimated position of at least one edge of the at least one structural element in the image, the set of points comprising, for each given row of a plurality of rows of the image, or for each given column of a plurality of columns of the image, at least one given point of the given row or of the given column of the image.

20. A non-transitory computer readable medium comprising instructions that, when executed by at least one or more processing circuitries, cause the at least one or more processing circuitries to perform:
obtaining an image of at least part of at least one structural element of a semiconductor specimen,
using the image to generate one or more filters,
performing a comparison between:
each given area of a plurality of areas of the image, and
the one or more filters,
and
determining, based on the comparison, a set of points of the image, informative of an estimated position of at least one edge of the at least one structural element in the image, the set of points comprising, for each given row of a plurality of rows of the image, or for each given column of a plurality of columns of the image, at least one given point of the given row or of the given column of the image.
